(19) United States
(12) Patent Application Publication
(10) Pub. No.: US 2020/0131630 A1
(43) Pub. Date: Apr. 30, 2020

(54) AEROSOL-FREE VESSEL FOR BUBBLING CHEMICAL PRECURSORS IN A DEPOSITION PROCESS

(71) Applicant: VERSUM MATERIALS US, LLC, Tempe, AZ (US)

(72) Inventors: Charles Michael Birtcher, Tempe, AZ (US); Gildardo Vivanco, Tempe, AZ (US); Sergei V. Ivanov, Tempe, AZ (US); William Sheehy, Tempe, AZ (US); Thomas Andrew Steidl, Tempe, AZ (US)

(21) Appl. No.: 16/603,757

(22) PCT Filed: Apr. 6, 2018
(86) PCT No.: PCT/US2018/026535

§ 371 Date: Oct. 8, 2019

Related U.S. Application Data
(60) Provisional application No. 62/483,784, filed on Apr. 10, 2017.

(51) Int. Cl. C23C 16/448; F17C 3/00

(52) U.S. Cl. CPC C23C 16/4486; F17C 2205/0352; F17C 2205/0311; F17C 3/00

(57) ABSTRACT

Described herein are aerosol-free vessels, delivery containers, systems and methods using same for providing improvements to precursor utilization in the containers for deposition process, as well as the cleaning and refilling of the containers. The clogging of valves and piping as some precursors decompose vapor are minimized. This invention prevents mist from forming and thus preventing clogging or wafer contamination from aerosols.

### CROSS-REFERENCE TO RELATED APPLICATIONS

This patent application is a non-provisional of U.S. provisional patent application Ser. No. 62/483,784, filed on Apr. 10, 2017, which is incorporated herein by reference in its entirety.

### BACKGROUND

The electronic device fabrication industry requires various chemicals as raw materials or precursors to fabricate integrated circuits and other electronic devices. Deposition processes such as, chemical vapor deposition (CVD) and atomic layer deposition (ALD) processes, are used in one or more steps during the manufacture of a semiconductor device to form one or more films or coatings on the surface of a substrate. In a typical CVD or ALD process, a precursor source that may be in a solid and/or liquid phase is conveyed to a reaction chamber having one of more substrates contained therein where the precursor reacts under certain conditions such as temperature or pressure to form the coating or film on the substrate surface.

There are several accepted technologies to supply a precursor vapor to a processing chamber. One process supplies the liquid precursor to a processing chamber in a liquid form with the flow rate controlled by a liquid mass flow controller (LMFC) and then the precursor is evaporated by a vessel at the point of use. A second process involves a liquid precursor being evaporated by heating and the resulting vapor is supplied to a chamber with the flow rate controlled by a mass flow controller (MFC). A third process involves bubbling a carrier gas upwardly through the liquid precursor. A fourth process involves enabling the carrier gas to flow over the surface of the precursor contained in a canister and carrying precursor vapor out of the canister and subsequently to the process tool.

Significant efforts have been made to increase vapor delivery of precursors that are susceptible to decomposing and causing clogging issues. For examples, “Dip Tube” designs (Applicants' own application: US20160333477, the entire disclosure is incorporated herein by reference) that reduce bubbling flow to vacuum. “Jet Tube” designs (Applicants' own application: US 62/335,396, the entire disclosure is incorporated herein by reference) that supply a carrier gas as a stream of laminar flow impinging the bed of precursor liquid; and “Non-dip tube” designs that provide a vapor sweep effect.

However, these designs are potentially facing some problems.

For Dip Tube designs, the deposition rate can be unacceptably low. And, if flow is not reduced, decomposed material builds up and clogging of valves can occur.

Jet Tube designs supply a carrier gas as a stream of laminar flow that impinges the bed of precursor liquid. While this solution solves the aerosol and clogging issues that bubbling to vacuum creates, it leads to variable deposition rates as liquid level reduces.

For Non-dip tube designs, chemical vapor delivery yields unacceptably low deposition rate.

Thus, there is a need in the art for a system and a method for delivery of precursors to a deposition or process chamber that aims to overcome the abovementioned drawbacks.

### SUMMARY

It is an object of the present invention to provide aerosol-free vessels, containers with the aerosol-free vessels mounted on the lids, systems and methods using the containers with the aerosol-free vessels mounted on the lids for delivering chemical precursors to a deposition or processing site and to overcome the abovementioned drawbacks.

On one aspect, the invention is an aerosol-free vessel to be mounted on a lid of a container for delivering a chemical precursor to a process tool, comprising: flow conduit having a start point, an end point, and directional turns between the start point and the end point; and

a fluid containing aerosols flowing from the start point;
wherein the directional turns maximize residence time of the aerosols in the aerosol-free vessel for phase change to vapor; and the flow conduit is gradually elevated from the start point to the end point.

In another aspect, the invention is a container for delivering a chemical precursor to a process tool, comprising:
a sidewall;
a base;
a lid;
at least one disclosed aerosol-free vessel mounted on the lid;
an inlet tube passing through the lid; and
an outlet passing through the lid;
wherein the outlet is in fluid communication with the exit of the last aerosol-free vessel.

In yet another aspect, the invention is a system for delivering a chemical precursor to a process tool, comprising:
at least one disclosed aerosol-free vessel;
a container for delivering a chemical precursor to a process tool, comprising:
   a sidewall;
   a base;
   a lid; and
   an outlet passing through the lid;
   wherein the lid is mounted with the disclosed at least one aerosol-free vessel; and
   the outlet is in fluid communication with the exit of the last aerosol-free vessel; and
   vapor of a chemical precursor from the outlet of the container.

In yet another aspect, the invention is a method for delivering a chemical precursor to a process tool, comprising:
providing at least one aerosol-free vessel;
providing a container comprising
   a sidewall;
   a base;
   a lid; and
   an outlet passing through the lid;
   wherein the lid is mounted with the disclosed at least one an aerosol-free vessel;
   and the outlet is in fluid communication with the exit of the last aerosol-free vessel;
deliver the vapor of a chemical precursor from the outlet of the container to a process tool.

The flow conduit of the aerosol-free vessel has a cross section with a shape selected from the group consisting of at least partial of a circle, at least of an oval, at least partial of a square, at least partial of a rectangle, and combinations thereof; or any other shape used in the art.

The aerosol-free vessel further comprises a cover to cover the flow conduit.

In some embodiments, the flow conduit of the aerosol-free vessel can be a pipe, with a spiral or a serpentine shape.

In some embodiments, the aerosol-free vessel comprises a top surface, wherein the top surface of the vessel has a shape selected from circle, oval, squire, rectangle, serpentine shape and combinations thereof.

The aerosol-free vessel further comprises mounting holes for mounting the aerosol-free vessel to a lid of a container or at least one of another aerosol-free vessel.

The aerosol-free vessel further comprises a screen at the start point of the flow conduit to reduce the size of the aerosols entering the aerosol-free vessel.

The aerosol-free vessel further comprises a heater for enhancing phase change to vapor

The container can have any shape. The shape includes but is not limited to cylindrical, rectangular cuboid, right cuboid, rectangular box, rectangular hexahedron, right rectangular prism, or rectangular parallelepiped; and with a cross section of circle, oval, square, rectangle or any other shape used in the art.

### BRIEF DESCRIPTION OF THE DRAWINGS

The present invention will hereinafter be described in conjunction with the appended figures wherein like numerals denote like elements:

FIG. 1 provides one design of an aerosol-free vessel.

FIG. 2 provides another design of an aerosol-free vessel.

FIG. 3 depicts a way to mount the aerosol-free vessel (with the cover open) as shown in FIG. 1 to the lid of a vessel.

FIG. 4 depicts the same mounting as shown in FIG. 3 with the cover closed on the aerosol-free vessel.

FIG. 5 depicts a way to mount the aerosol-free vessel (with the cover open) as shown in FIG. 2 to the lid of a vessel.

FIG. 6 depicts the same mounting as shown in FIG. 5 with the cover closed on the aerosol-free vessel.

### DETAILED DESCRIPTION

Described herein are aerosol-free vessels; the containers having aerosol-free vessels installed, mounted or machined on their lids; and systems comprising the containers and chemical precursors for a process tool such as a deposition reactor in a chemical vapor deposition (CVD) or atomic layer deposition (ALD) process; and methods of use the systems.

More specifically, described herein are the aerosol-free vessels. The aerosol-free vessel can be installed onto the lids of existing containers that will allow bubbling to vacuum without transporting aerosols out of the container. Since only carrier gas and chemical vapors exit the container, the build-up of decomposed chemical will be limited, and clogging can be prevented. Also, chemical aerosols will not reach the wafer and cause contamination.

In order to aid in describing the invention, some terms are defined and used in the specification.

The term “conduit”, may be used in the specification and claims, refers to one or more structures through which fluids can be transported between two or more components of a system. For example, conduits can include pipes, ducts, passageways, and combinations thereof that transport liquids, vapors, and/or gases.

The term “aerosol” as used in the specification and claims, refers to tiny liquid droplets suspended in a gas; such as, mist which consists of very fine particles of water suspended in air.

The term “flow communication,” as used in the specification and claims, refers to the nature of connectivity between two or more components that enables liquids, vapors, and/or gases to be transported between the components in a controlled fashion (i.e., without leakage). Coupling two or more components such that they are in flow communication with each other can involve any suitable method known in the art, such as with the use of welds, flanged conduits, gaskets, and bolts.

The term “electric communication”, as used in the specification and claims, refers to the use of electronics to operate the system or method described herein and can be constructed as separate system to control flow rates, temperature and other physical attributes.

Some directional terms may be used in the specification and claims to describe portions of the present invention (e.g., upper, lower, left, right, etc.). These directional terms are merely intended to assist in describing and claiming the invention, and are not intended to limit the invention in any way. In addition, reference numerals that are introduced in the specification in association with a drawing figure may be repeated in one or more subsequent figures without additional description in the specification in order to provide context for other features.

The disclosed embodiments satisfy the need in the art by providing the structure that avoids the formation of aerosols and to plugging the inlet tube with solids.

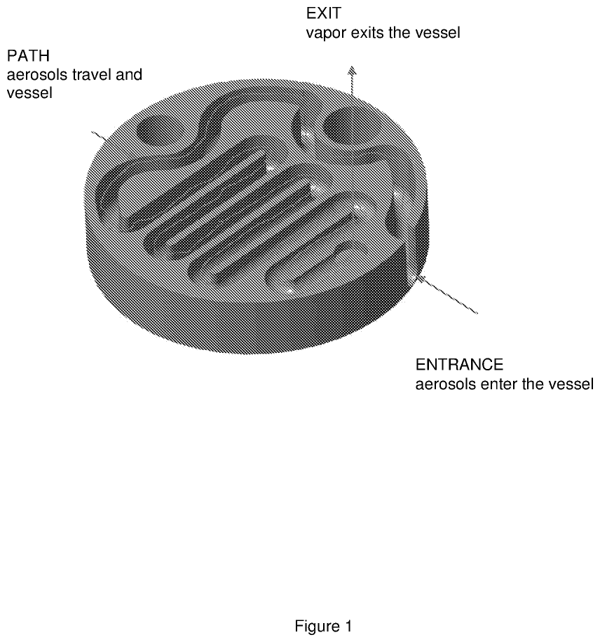

In one of the disclosed embodiments, the aerosol-free vessel is shown in FIG. 1. Please note that, the aerosol-free vessel in FIG. 1 is shown as upside down to display the details.

As shown in FIG. 1, the aerosol-free vessel has s flow conduit (or flow path), an entrance (or a start point for the conduit), and an exit (or an end point for the conduit). The fluid containing aerosols flows from the start point towards the end point.

The aerosol-free vessel can also have mounting holes for mounting itself to a lid of a container.

The flow path can be tubular having a cross section (by making a straight cut through conduit at right angle to the surface of the cover) of any shape, such as a shape selected from the group consisting of at least partial of a circle, at least of an oval, at least partial of a square, at least partial of a rectangle, and combinations thereof or any other shape used in the art.

The flow conduit begins with a large opening (i.e. larger cross section area) at the entrance and gradually reduces in size (decreased or smaller cross section area) and ends at the exit. That is, the flow conduit has decreased cross section areas from the start point to the end point.

The flow conduit has many directional turns between the start point and the end point to maximize the residence time of aerosols in the vessel to facilitate the phase change to vapor.

The flow path is gradually elevated from the start point to the end point.

The directional turns also provide the repeated surface contacts for aerosols or any condensed material that do not go through the phase change to vapor, so they can drop out of suspension and flow/slip down the elevated flow path in reverse direction as liquid and eventually drip back into the container from the start point (entrance).

If residence time is still insufficient, then heater such as heater cartridges can be installed and used to heat the aerosol-free vessel. Thus, heat conduction from the heater will ensure a complete phase change from aerosols to vapor.

In order to reduce aerosols entering the vessel, a screen can also be added at the entrance.

The aerosol-free vessels can be stacked to ensure that vapor is free of aerosols at the exit of the vessel.

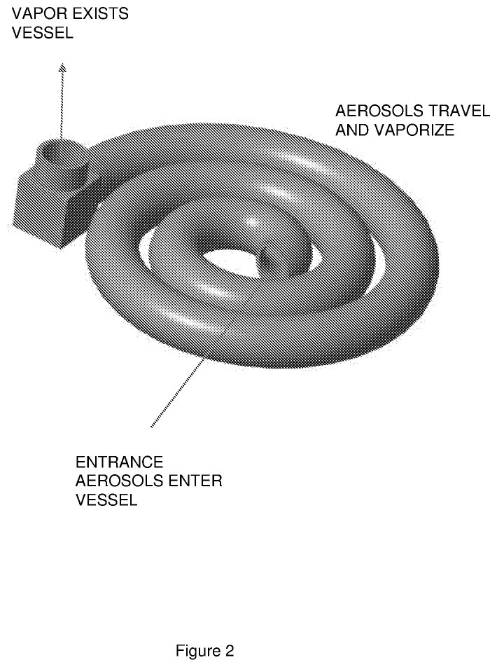

Another type of the flow path for a different design of the aerosol-free vessels is shown in FIG. 2. The flow path or the flow conduit is in a spiral pipe shape or any serpentine pipe shape.

The flow conduit is shown having a circular shape in FIGS. 2, 5 and 6, as an example.

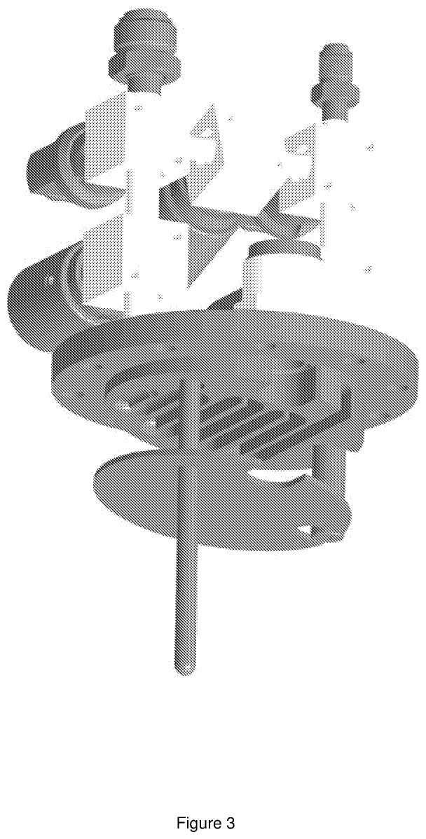

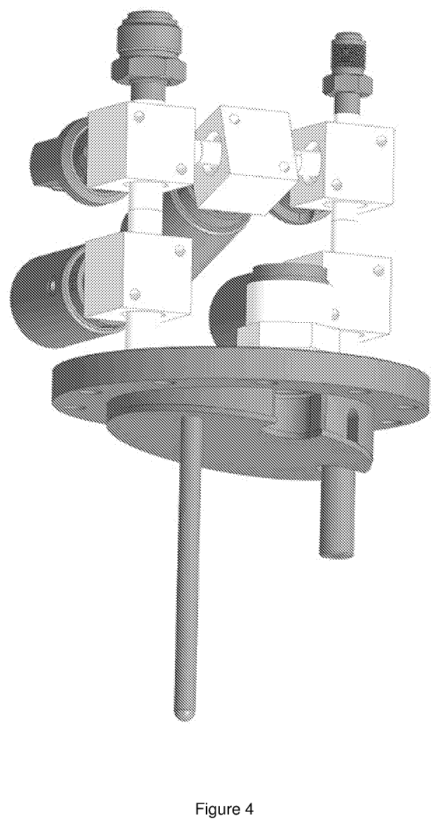

The aerosol-free vessel can have mounting units for mounting the vessel on a surface. The aerosol-free vessel also has a piece of cover, which is not shown in FIG. 1 but is shown in FIGS. 3 and 4, to cover the whole flow path.

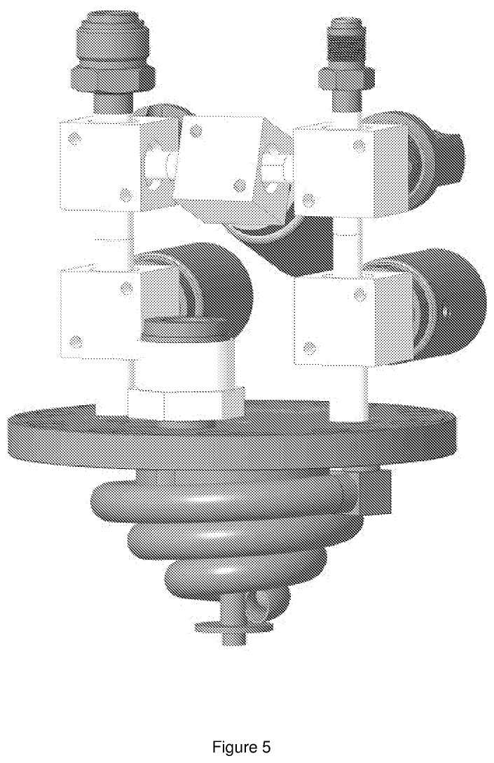

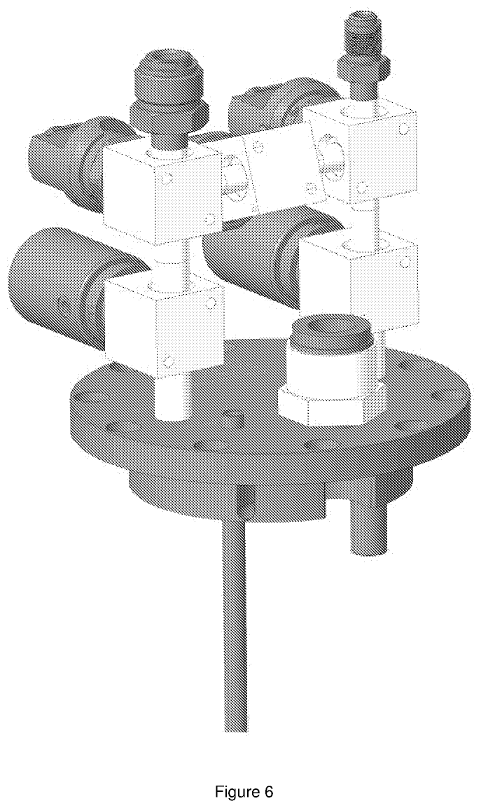

As shown in FIGS. 5 and 6, the aerosol-free vessel also has a center cone shape piece to hold the flow path so that the flow path is gradually elevated from the start point(entrance) to the end point (exit). The aerosol-free vessel further has a cover to cover the whole path.

The spiral pipe or serpentine shaped pipe again provide the repeated surface contacts for aerosols or any condensed material that do not go through the phase change to vapor, so they can drop out of suspension and flow/slip down the flow path in reverse direction as liquid and eventually drip back into the container from the start point (entrance).

The aerosol-free vessel has a top surface, with a shape selected from circle, oval, square, rectangle, serpentine shape, and combinations thereof.

An aerosol-free vessel or a stack of aerosol-free vessels can be installed or mounted onto the lid of an existing container that will allow bubbling to vacuum without transporting aerosols out of the container.

Since only carrier gas and chemical vapors exit the container, the build-up of decomposed chemical will be limited, and clogging can be prevented.

The containers that are used to deliver chemical precursor will have an aerosol-free vessel or a stack of aerosol-free vessels mounted to their lids.

The containers can have any shapes, including but are not limited to cylindrical, rectangular cuboid, right cuboid, rectangular box, rectangular hexahedron, right rectangular prism, or rectangular parallelepiped; and with a cross section of circle, oval, square, rectangle or any other shape used in the art. The volume of the containers to the process tool ranges from 100 milliliters (ml) to 10 liters. The containers described herein may further include a means for initially filling and cleaning the reservoir.

The material of construction of the vessels is typically stainless steel but may be made from other materials depending on the reactivity of the precursor with the material in question. The materials of construction of the apparatus described herein exhibit one or more of the following characteristics: chemically compatible to prevent corrosion or reaction with the precursor, strong enough to support the pressures and vacuum forces used, and generally leak tight to hold vacuum from 1 mTorr to 500 mTorr depending on the process chemicals and/or solvent in use. The containers also contain one or a plurality of valves and ports and sensors, to allow access to the precursor.

In certain embodiment, the containers have a large cap, lid, or bung that is fastened such as by screws or other means onto the top of the reservoir and sealed with elastomeric or metal o-rings and/or gaskets. This lid has a flat surface that is used for the mounting of an aerosol-free vessel or a stack of aerosol-free vessels and for the installation of other parts such as level sense probes.

There are several ways to mount the vessel onto the lid of a vessels.

In some embodiments, the vessel can be mounted to the lid of a vessel with multiple bolts screwed onto the lid as shown in FIGS. 3 to 6. The exit of the vessel is a tube or a flat surface that aligns with the outlet port of the lid.

In some embodiments, an alternative mounting method is to use clips to support the vessel.

In some embodiments, the vessel flow paths can be machined off the lid and separately a cover can be machined to mate with the lid

In some improved embodiments, the vessel and lid can be manufactured as a single part. One such method is by using 3D printing.

In the claims, letters may be used to identify claimed method steps (e.g. a, b, and c). These letters are used to aid in referring to the method steps and are not intended to indicate the order in which claimed steps are performed, unless and only to the extent that such order is specifically recited in the claims.

1. An aerosol-free vessel, comprising:
flow conduit having a start point, an end point, and directional turns between the start point and the end point; and
a fluid containing aerosols flowing from the start point;
wherein
the directional turns maximize residence time of the aerosols in the aerosol-free vessel for phase change to vapor; and
the flow conduit is gradually elevated from the start point to the end point.

2. The aerosol-free vessel of claim 1, wherein the flow conduit has a cross section with a shape selected from the group consisting of at least partial of a circle, at least of an oval, at least partial of a square, at least partial of a rectangle, and combinations thereof;
wherein cross section area of the flow conduit decreases from the stat point to the end point.

3. The aerosol-free vessel of claim 1, further comprises a cover to cover the flow conduit.

4. The aerosol-free vessel of claim 1, wherein the flow conduit is a pipe having a spiral or a serpentine shape.

5. The aerosol-free vessel of claim 1, further comprises a top surface, wherein the top surface of the vessel has a shape selected from circle, oval, square, rectangle, serpentine shape, and combinations thereof.

6. The aerosol-free vessel of claim 1, wherein the start point of the flow conduit comprises a screen to reduce aerosols entering the aerosol-free vessel.

7. The aerosol-free vessel claim 1, further comprises a heater for enhancing phase change to vapor.

8. The aerosol-free vessel of claim 1, further comprises mounting holes for mounting the aerosol-free vessel to a lid of a container or at least one of another aerosol-free vessel.

9. A container for delivering a chemical precursor to a process tool, comprising:
a sidewall;
a base;
a lid;
at one aerosol-free vessel in claim 1 mounted on the lid;
an inlet tube passing through the lid; and
an outlet passing through the lid;
wherein the outlet is in fluid communication with the exit of the last aerosol-free vessel.

10. A system for storage and delivery of a chemical precursor to a process tool, comprising:
a container for delivering a chemical precursor to a process tool, comprising:
a sidewall;
a base;
a lid;
at one aerosol-free vessel in claim 1 mounted on the lid;
an inlet tube passing through the lid; and
an outlet passing through the lid;
wherein the outlet is in fluid communication with the exit of the last aerosol-free vessel; and
vapor of a chemical precursor from the outlet of the container.

11. A method for storage and delivery of a chemical precursor to a process tool, comprising:
providing the system in claim 10, and
deliver the vapor of the chemical precursor from the outlet of the container to the process tool.
